(19) United States
(12) Patent Application Publication
(10) Pub. No.: US 2010/0026321 A1
(43) Pub. Date: Feb. 4, 2010

(54) CIRCUIT SYSTEM FOR A MICROMECHANICAL SENSOR ELEMENT HAVING A CAPACITOR ARRAY

(76) Inventor: Oliver Schatz, Reutlingen (DE)

Correspondence Address: KENYON & KENYON LLP, ONE BROADWAY, NEW YORK, NY, 10004, US

(21) Appl. No.: 12/305,164

(22) PCT Filed: Jul. 31, 2007
(86) PCT No.: PCT/EP07/57865

§ 371 Date: May 4, 2009

(30) Foreign Application Priority Data
Sep. 29, 2006 (DE) 10 2006 046 403.6

(51) Int. Cl. G01R 27/26

(52) U.S. Cl. 324/686

(57) ABSTRACT

A circuit system for a micromechanical sensor element having a capacitor array and a downstream amplifier for the useful signal of the capacitor array is described. Using this circuit system, setpoint deviations of the base capacitance of the capacitor array can easily be compensated. For this purpose, the circuit system includes a circuit using which a control signal is generated, which is decoupled from the useful signal of the capacitor array, but is a function of the base capacitance of the capacitor array, which is conveyed to the amplifier for controlling the gain.

### FIELD OF THE INVENTION

The present invention relates to a circuit system for a micromechanical sensor element having a capacitor array and a downstream amplifier for the useful signal of the capacitor array.

### BACKGROUND INFORMATION

A wide variety of implementations of micromechanical capacitor arrays within the scope of sensor elements are available. The component structure of such a capacitor array is generally determined by the intended use and the location of the particular sensor element. Diaphragm structures are mostly used in the case of pressure sensors and sound transducers. The one electrode of the capacitor array is formed here by a micromechanically manufactured diaphragm, with a stationary counterelectrode being situated on the opposite side. The diaphragm is deformed in the event of a pressure or sound impact, thereby changing the distance to the counterelectrode and thus the capacitance of the capacitor array formed by the diaphragm and the counterelectrode.

Micromechanical sensor elements are mass-produced by appropriately processing wafers. The mechanical properties of the layers, which are deposited and structured during manufacturing, have a direct effect on the sensor characteristics of the produced components. The distance between the electrode and the counterelectrode in diaphragm sensors “identical in construction” may thus vary greatly, by applying stress in the manufacturing process, for example, which results in differences in the base capacitance and thus also in the sensitivity.

Various measures for avoiding such manufacturing-related quality variations in the mass production of micromechanical sensor elements having a capacitor array are used.

A still stricter monitoring of the micromechanical manufacturing process is initially strived for. In addition to this, a uniform quality standard may be achieved by a quality check at the end of the manufacturing process where those components which do not meet the quality requirements are identified and rejected. The quality variations of micromechanical sensor elements are compensated in some cases by an electrical calibration of the whole product. For this purpose, the sensitivity of a sensor element is determined once and set to a predefined value with respect to its circuitry.

All three measures cited above are relatively cost-intensive and are difficult to be reconciled with the requirements of mass production.

### SUMMARY

An object of the present invention is to provide a circuit system using which setpoint deviations of the base capacitance of a capacitor array may easily be compensated and which, in addition, may easily be integrated on a micromechanical sensor element.

This is achieved according to the present invention by a circuit using which a control signal is generated which is decoupled from the useful signal of the capacitor array, but is a function of the base capacitance of the capacitor array.

This control signal is then conveyed to the amplifier for the useful signal for controlling the gain.

According to example embodiments of the present invention, the working point of the sensor element is intrinsically adjusted by suitable signal processing. It has been found according to the present invention that, parallel to detecting the useful signal, the base capacitance of the capacitor array may also be determined using simple circuitry. Furthermore, it has been found that, on the basis of the actual base capacitance of the capacitor array, the sensitivity of the sensor element may be adjusted—at least within certain limits—using simple circuitry by appropriately amplifying the useful signal. This makes it possible to substantially reduce the sensor element rejects as well as the costs for a quality check and/or the expenditure for an electrical calibration of the whole product.

There are basically different options for implementing a circuit system according to the example embodiment of the present invention, both analogously and digitally; the integratability on a micromechanical component is to be particularly emphasized.

A circuit block, which converts the capacitance of the capacitor array into a proportional voltage, is frequently situated downstream from the capacitor array of a sensor element. In one specific example embodiment of the present invention, a signal branching having at least two output paths is situated downstream from this signal block. In applications using a relatively high-frequency useful signal, e.g., in a sound transducer, the useful signal is obtained from the voltage signal in a first output path with the aid of a high-pass filter and fed into an amplifier. A control signal for this amplifier is generated in a second output path by determining the DC voltage component of the voltage signal which is a function of the base capacitance of the capacitor array. The voltage signal is conducted via a low-pass filter for this purpose.

In another specific example embodiment of the present invention, which is also suitable for applications using useful signals in a lower frequency range, e.g., for a dynamic pressure sensor, an arrangement provided for applying an AC voltage to the capacitor array, this AC voltage being used as a test voltage for determining the base capacitance. The frequency range of the test voltage should differ from that of the useful signal, so that both the test voltage component and the useful signal may be extracted from the output signal of the capacitor array using suitable filters. A control signal for the amplifier of the useful signal is subsequently generated from the test voltage component.

### BRIEF DESCRIPTION OF THE DRAWINGS

As discussed above, there are different options to configure and refine the present invention in an advantageous manner. For this purpose, reference is made to the description below of two exemplary embodiments of the present invention depicted in the figures.

FIG. 1 shows a first circuit system according to the present invention for a sensor element having a capacitor array.

FIG. 2 shows a second circuit system according to the present invention for a sensor element having a capacitor array.

### DETAILED DESCRIPTION OF EXAMPLE EMBODIMENTS

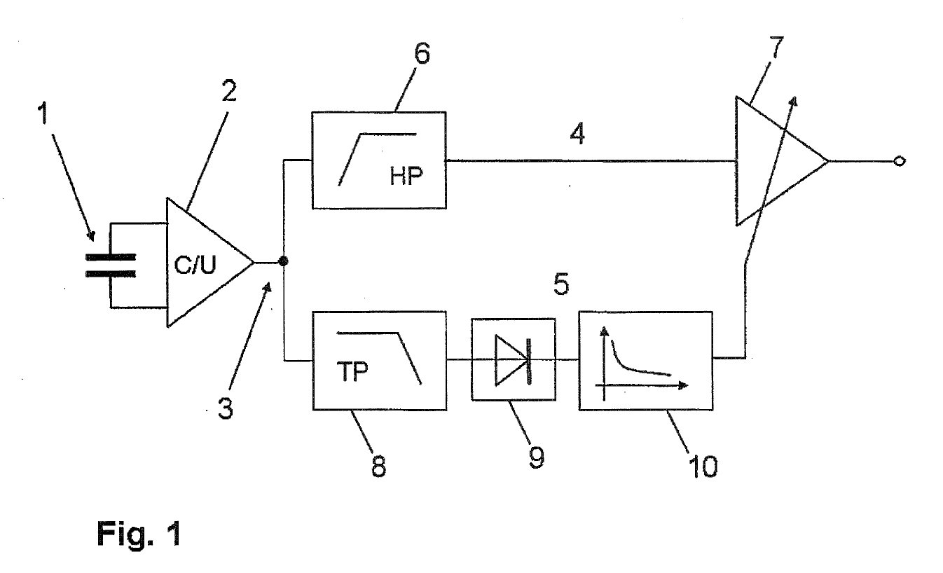

The circuit system shown in FIG. 1 is designed for a capacitive diaphragm sensor which could be used as a sound transducer, for example, since a relatively high-frequency useful signal is to be expected. Capacitor array 1 is formed here by a micromechanically implemented diaphragm and a rigid counterelectrode. The capacitance of capacitor array 1 is converted into a proportional voltage by circuit block 2. A downstream signal branching 3 splits the voltage signal into two output paths 4 and 5. In the one output path 4, the voltage signal is fed, via a high-pass filter 6, into an amplifier 7 whose gain is controllable. In the other output path 5, a control signal is generated and conveyed to the control input of amplifier 7. For this purpose, the DC voltage component of the voltage signal, as a function of the base capacitance of capacitor array 1, is determined by conducting the voltage signal first via a low-pass filter 8 and then rectifying it using a rectifier 9. The gain factor for amplifier 7 is then determined with the aid of a characteristic curve 10. High-pass filter 6 and low-pass filter 8 must be dimensioned in such a way that the useful signal is reliably decoupled from the control signal.

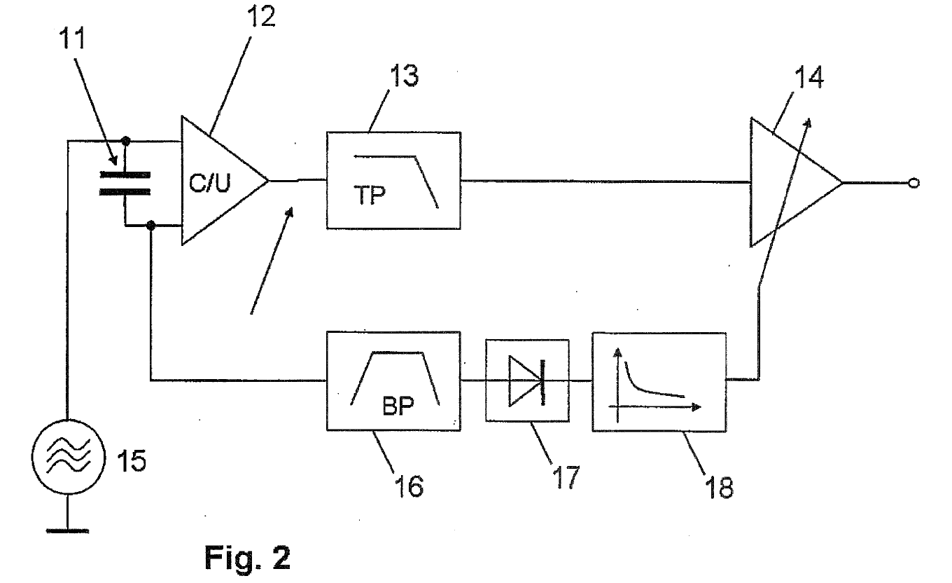

The circuit system shown in FIG. 2 is also designed for a capacitive diaphragm sensor. Here also, the capacitance of capacitor array 11 is converted into a proportional voltage by a circuit block 12. A low-pass filter 13 is situated downstream from this circuit block 12, using which the useful signal is extracted from the output signal of capacitor array 11. The useful signal is then conveyed to a controllable amplifier 14. In the case of the circuit system shown in FIG. 2, capacitor array 11 is connected to a high-frequency test voltage 15 with whose aid the AC resistance of capacitor array 11 and thus its base capacitance may be ascertained. The test voltage should be in a different frequency range than the useful signal. The test voltage component is filtered out of the output signal of capacitor array 11 with the aid of a bandpass filter 16. A control signal for amplifier 14 is then generated out of it by rectifying the signal by a rectifier 17 and determining the gain factor with the aid of a characteristic curve 18.

Finally is should be pointed out that, with the aid of the example circuit systems according to the present invention, not only the sensitivity of a micromechanical sensor element having a capacitor array may be adjusted in a targeted manner, but also other variables may be controlled, such as the offset of the sensor element, for example.

1-3. (canceled)

4. A circuit system for a micromechanical sensor element, comprising:
a capacitor array;
a downstream amplifier for a useful signal of the capacitor array; and
a circuit adapted to generate a control signal, decoupled from the useful signal of the capacitor array but a function of a base capacitance of the capacitor array, the control signal being conveyed to the amplifier for controlling gain.

5. The circuit system as recited in claim 4, wherein the circuit includes a circuit block downstream from the capacitor array which converts a capacitance of the capacitor array into a proportional voltage, wherein the circuit has a signal branching downstream from the circuit block having at least two output paths, so that a signal is fed as the useful signal in a first output path via a high-pass filter into the amplifier, and so that the signal is conducted in a second output path via a low-pass filter to obtain the control signal for the amplifier.

6. The circuit system as recited in claim 4, wherein the circuit includes a circuit block downstream from the capacitor array which converts a capacitance of the capacitor array into a proportional voltage which is fed as the useful signal into the amplifier via a filter, an arrangement adapted to apply an AC voltage to the capacitor array which is used as a test voltage for determining a base capacitance, and to filter a test voltage component out of an output signal of the capacitor array and to generate a control signal for the amplifier from the test voltage component.
